(19) United States
(12) Patent Application Publication
(10) Pub. No.: US 2001/0000497 A1
(43) Pub. Date: Apr. 26, 2001

(54) Method and apparatus for removing a material layer from a substrate

(76) Inventors: Yakov Epshteyn, Phoenix, AZ (US); Sumit Guha, San Jose, CA (US); Yehiel Gotkis, Fremont, CA (US); William J. Bellamak, Gilbert, AZ (US)

Correspondence Address: James L. Farmer, Esq., SpeedFam-IPEC Corporation, 305 North 54th Street, Chandler, AZ, 85226, US

(21) Appl. No.: 09/736,472

(22) Filed: Dec. 13, 2000

Related U.S. Application Data
(63) Continuation of application No. 09/415,898, filed on Oct. 8, 1999.

(51) Int. Cl. H01L 21/302; H01L 21/461

(52) U.S. Cl. 438/691; 438/; 438/692; 438/690

(57) ABSTRACT

An improvement to chemical-mechanical polishing. The improvement includes using a buffing pad having a geometrically optimized shape along with optimizing the buff head diameter, offset O and overlay L. In one embodiment, the buffing pad is smaller than the buff head and is mounted eccentrically. In another embodiment, the buffing pad has a generally square outer shape. In another embodiment, the buff pad is circular and is the same size as the circular buff head. In another embodiment, the buffing pad has at least three radially extending arms. The optimal configuration is determined iteratively for a selected process by changing the buffing pad shape, buff head diameter, the offset and the overlay. For example, increasing the offset generally tends to increase the removal rate toward the edge of the wafer. Increasing the overlap generally tends to increase the removal rate toward the center of the wafer. Removing portions of the buffing pad near the pad's edge tends to decrease the removal rate over the entire wafer radius but more so near the center and the edge of the wafer. By empirically testing various configurations, the optimal configuration can be found for a particular application.

The invention further provides a method of chemical-mechanical polishing of a semiconductor device utilizing a combination of polishing steps, including a first polishing step on a primary polish station using a first slurry and a second polishing step on a buff station using a second slurry. The method may be used on a material layer, such as copper or tungsten, deposited over a barrier layer covering a dielectric layer. The first polishing step is stopped after the material layer has been substantially removed and the second polishing step is stopped after the barrier layer has been substantially removed. An end-point detection system may be used to determine when the material and barrier layers have been substantially removed.

### CROSS-REFERENCE TO RELATED APPLICATIONS

1. This application is a continuation in part of U.S. Ser. No. 09/415,898 filed on Oct. 8, 1999, and of common assignee.

### FIELD OF THE INVENTION

2. The present invention relates to integrated circuit manufacturing technology, and more particularly, to buff systems typically used in conjunction with chemical-mechanical polishing of semiconductor wafers. Still more particularly, the present invention relates to a method for removing a barrier layer from a substrate to improve processing time and polishing quality.

### BACKGROUND OF THE INVENTION

3. Currently, various photolithographic optics-based processes are used in the manufacture of integrated circuits on semiconductor wafers. Because these optics-based processes generally require accurate focusing in order to produce a precise image, the surface planarity of the wafer is an important issue.

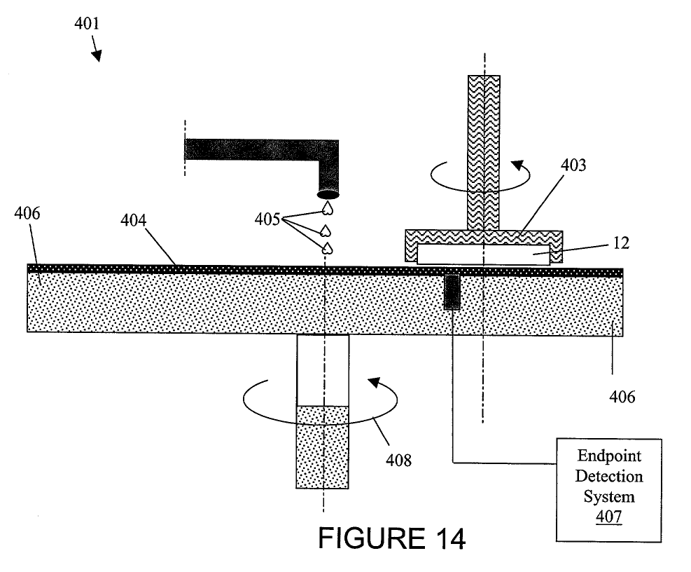

4. There are several techniques for planarizing the surface of a semiconductor wafer. One technique is chemical-mechanical polishing (CMP). A standard CMP tool is shown in FIG. 14. These tools generally include a carrier 403 to mount a wafer 12 and a polish pad 404 supported by a polishing platen 406. The CMP tool 401 causes the polish pad 404 and the wafer 12 surface to come into contact, typically applying a specified pressure between the polish pad 404 and the wafer 12 surface. The CMP tool 401 also imparts a relative motion between the wafer 12 surface and the polish pad 404 by orbiting or rotating the polishing pad about an axis and/or rotating the wafer carrier 403. In addition, the CMP tool typically introduces slurry 405 at the interface between the polishing pad 404 and the wafer surface 12. The slurry 405 can have abrasive particles suspended in a chemical solution that reacts with selected materials on the wafer 12 surface. The pressure, slurry and relative motion effectuate the polishing. After polishing, a secondary buff step is often used to remove microscratches and strongly adhering particles and to provide a final light polish. After buffing, the wafers 12 go through a clean up and drying process to remove residual slurry, metal particles, and other potential contaminants from its surface.

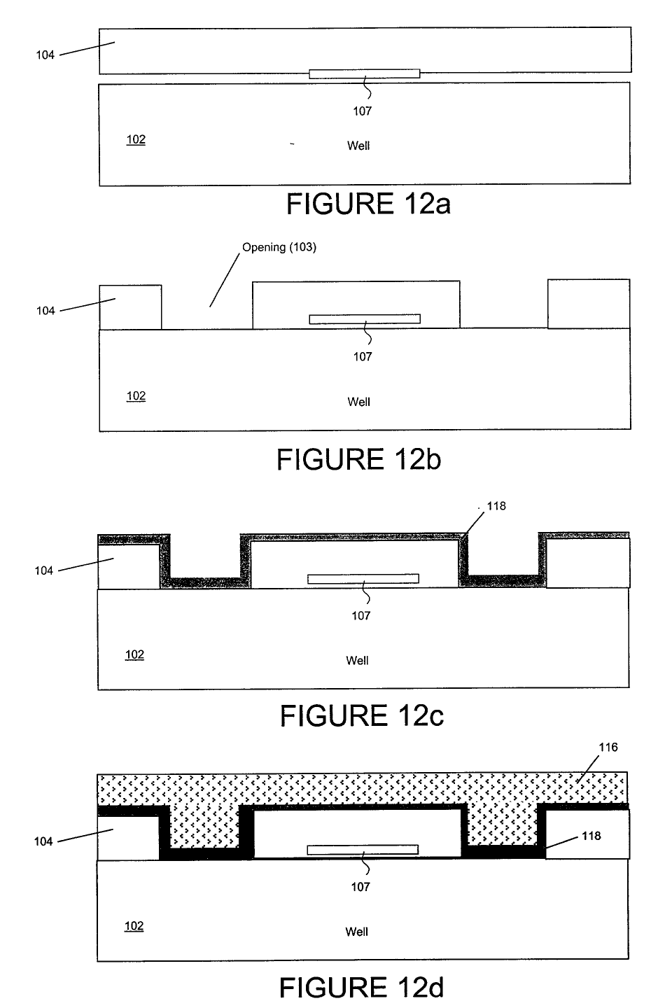

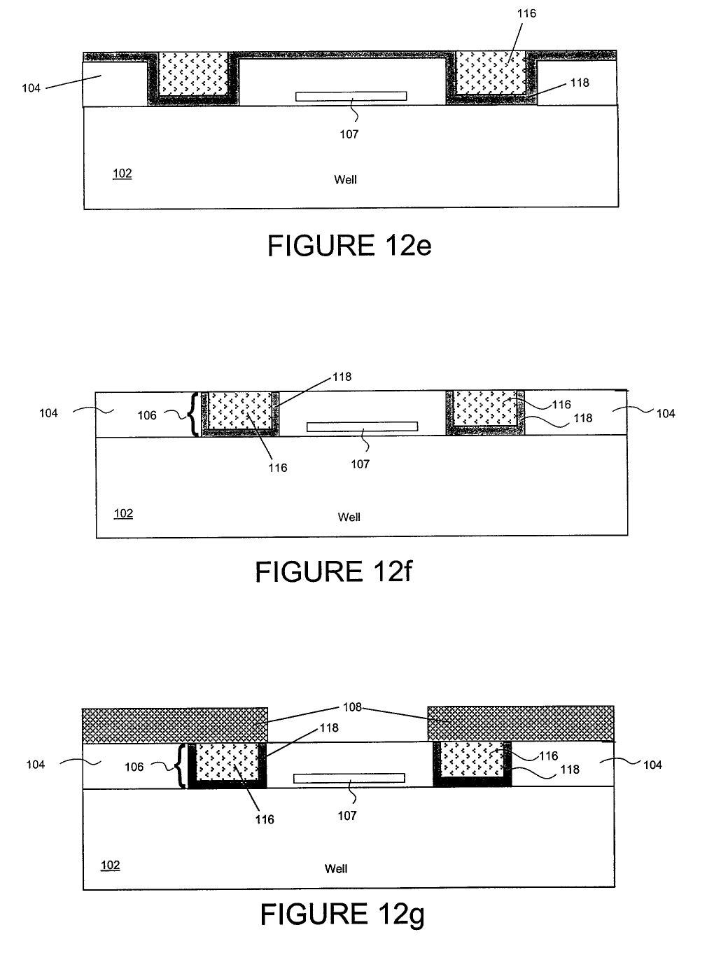

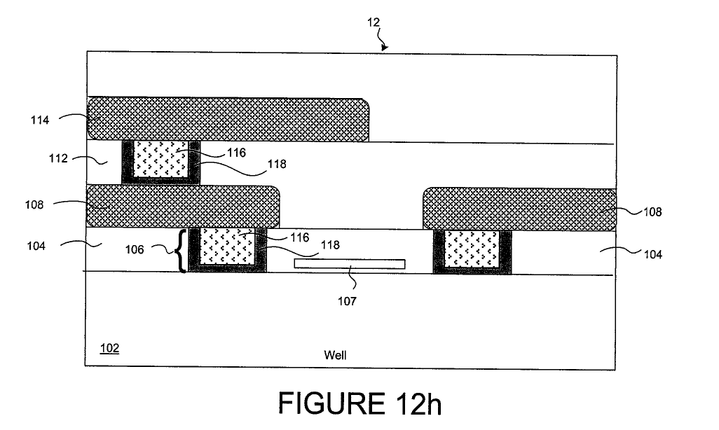

5. Integrated circuits manufactured today are made up of literally millions of active devices such as transistors and capacitors formed in a semiconductor wafer. Integrated circuits rely upon an elaborate system of metalization in order to connect the active devices into functional circuits. A typical multilevel interconnect 12 is shown in FIG. 12d. Active devices such as MOS transistors 107 are formed in and on a silicon substrate or well 102. An interlayer dielectric (ILD) 104, such as SiO₂, is formed over silicon substrate 102. ILD 104 is used to electrically isolate a first level of metalization which is typically aluminum (Al), or copper (Cu), from the active devices formed in substrate 102. Metalized contacts or vias 106 electrically couple active devices formed in substrate 102 to interconnections 108 of the first level o0f metalization. In a similar manner contacts 106 electrically couple interconnections 114 of a second level of metalization to interconnections 108 of the first level of metalization. Contacts 106 typically comprise a metal 116 such as tungsten (W) surrounded by a barrier metal 118. Additional ILD/contact 106 and metalization layers can be stacked one upon the other to achieve the desired interconnections.

6. Most metal structures are formed on a wafer with a barrier layer deposited underneath so as to act as an adhesion layer to provide low electrical resistance and prevent diffusion of the metal into the dielectric layer. Common barrier layers used in integrated circuit manufacturing are titanium (Ti), titanium nitride (TiN), and tantalum (Ta). The barrier layers have very different chemical and physical properties than the top metal layer which is typically comprised of tungsten, aluminum, or copper. Accordingly, the polishing behavior of the barrier layers can be quite different than their respective top metal layers. Applicants have noticed that to maximize the efficiency of the planarization process, both the polishing slurry and pad configuration need to be compatible with the material being polished.

7. A common practice in semiconductor manufacturing is the formation of metal plugs, typically tungsten plugs, which serve as contacts and vias between two layers of metal. As above, barrier layers comprising Ti, TiN, Ta, or a combination of these are commonly inserted between the underlying dielectric layer and the plug metal to aid in adhesion and reduce diffusion of the plug metal into the underlying dielectric layer. Due to the chemical properties which may be chosen for use in slurry, most commercially available tungsten polishing slurries can polish a tungsten film with at least 3 to 10 times higher removal rate than polishing Ti. For this reason, the slurry composition is typically changed between the steps of removing a metal layer and a barrier layer. Thus, a further disadvantage that occurs in a conventional CMP process is the interaction between multiple slurries of differing chemical composition when used on the same polishing pad.

8. Typically, both the metal and barrier layers are removed on the same polish pad in the presence of one or more slurry compositions. However, Applicant discovered that removing both the metal and barrier layers on the same polish pad creates various problems for the process, depending on the materials being planarized. For example, when copper is planarized, a multi-step process is used in which the slurry is changed and the polish pad conditioned between removal of the metal layer and removal of the barrier layer. Typically, to avoid any unwanted interaction between different slurries, deionized water is used to rinse the first slurry before a second slurry is applied to the primary polish station. This rinsing process may take several seconds which increases processing time. Even after rinsing, residual amounts of the first slurry may remain on the polish pad which might introduce the possibility of reacting with either the second slurry or the material being planarized..

9. In another example, when tungsten is planarized in a CMP tool, there is only one slurry used for removing both the tungsten and barrier layers. Using a conventional system, however, both layers are still removed on the same polish pad. The slurry used is chemically reactive to tungsten and therefore, a certain amount of undesirable tungsten erosion in the plug and/or metal structures can occur when removing the barrier layer. Also, the down-force exerted on the wafer during polishing at a primary polishing station is typically about 4 psi which reduces the planarity of the wafer surface as compared to a lower pressure, and thus creates the possibility of creating undesired open or closed circuits within the wafer.

10. What is needed is a method for removing the barrier layer from the front surface of a wafer without the undesired side effects associated with removal of the barrier layer on the same polish pad as the metal layer.

### SUMMARY OF THE INVENTION

11. In accordance with aspects of the present invention, an improvement is provided to chemical-mechanical polishing machines. The improvement includes using a buffing pad having a geometrically optimized shape, along with an optimized configuration of the offset O and the overlay L (which is a function of the buff head diameter and the offset). In one embodiment, the pad is circular but mounted to the buff head eccentrically. In another embodiment, the buffing pad has a generally square outer shape. In another embodiment, the buffing pad has at least three radially extending arms.

12. In another aspect of the present invention, the optimal configuration is determined iteratively for a selected process by changing the offset, overlay, buff head diameter and pad shape. For example, increasing the offset tends to increase the removal rate toward the edge of the wafer (in general). Increasing the overlap generally tends to increase the removal rate in the center of the wafer.

13. Besides changing the offset, overlap and buff head diameter, the shape of the pad itself can be modified to tailor the removal rate profile. Typically, the desired removal rate profile is as uniform as possible. In the embodiments of the present invention described herein, the removal characteristics of the system were optimized to balance the removal rate between the edge and the center. However, when optimizing only the overlap, offset and buff head diameter, the resulting removal rate profile was both edge and center fast. To further increase the uniformity of the removal rate profile, pad material was removed near the edge of the buff head so that the removal rate would decrease at both the edge and the center. This produced a significant improvement in uniformity. The best pad shape tested so far is a round pad smaller than the buff head (86% in diameter) and mounted to the buff head eccentrically and tangent at one point on its edge.

14. The present invention further provides a method and apparatus for planarizing a front surface of a wafer. The invention improves the planarization process by providing a method and apparatus for removal of a first material layer on a main polish station, and removal of a second material layer, preferably a barrier layer, on a buff station.

### BRIEF DESCRIPTION OF THE DRAWINGS

15. The foregoing aspects and many of the attendant advantages of this invention will become more readily appreciated as the same become better understood by reference to the following detailed description, when taken in conjunction with the accompanying drawings, wherein:

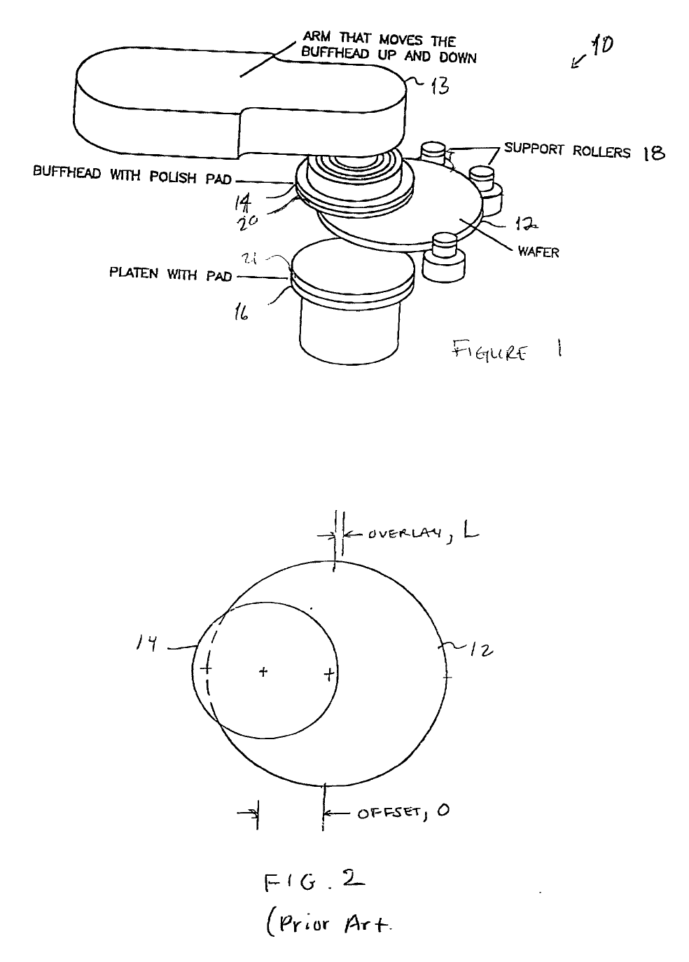

16. FIG. 1 is a simplified perspective view of a conventional buffing system.

17. FIG. 2 is a plan view illustrating the parameters overlay and offset of FIG. 1.

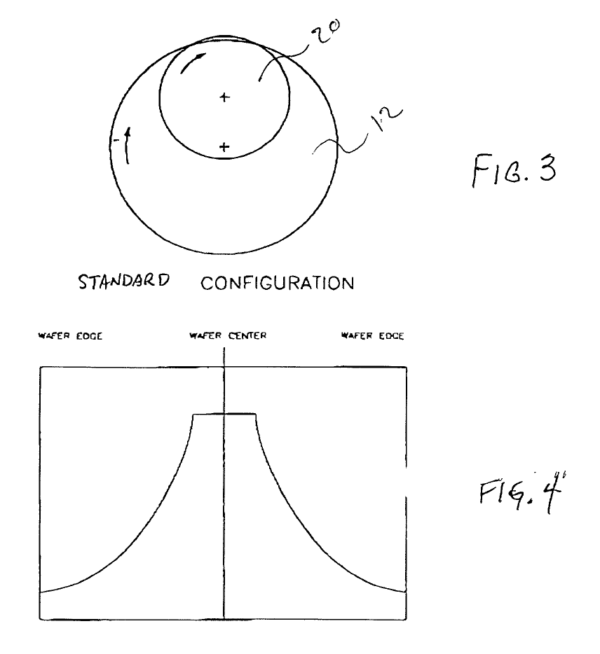

18. FIG. 3 is a scaled plan view illustrating the standard buffing unit configuration.

19. FIG. 4 is a diagram illustrating the removal rate profile obtained using the buffing unit configuration of FIG. 3 and illustrates the inherent center fast property of a conventional configuration.

20. FIG. 5 is a scaled plan view of a first test configuration.

21. FIG. 6 is a scaled plan view of a second test configuration.

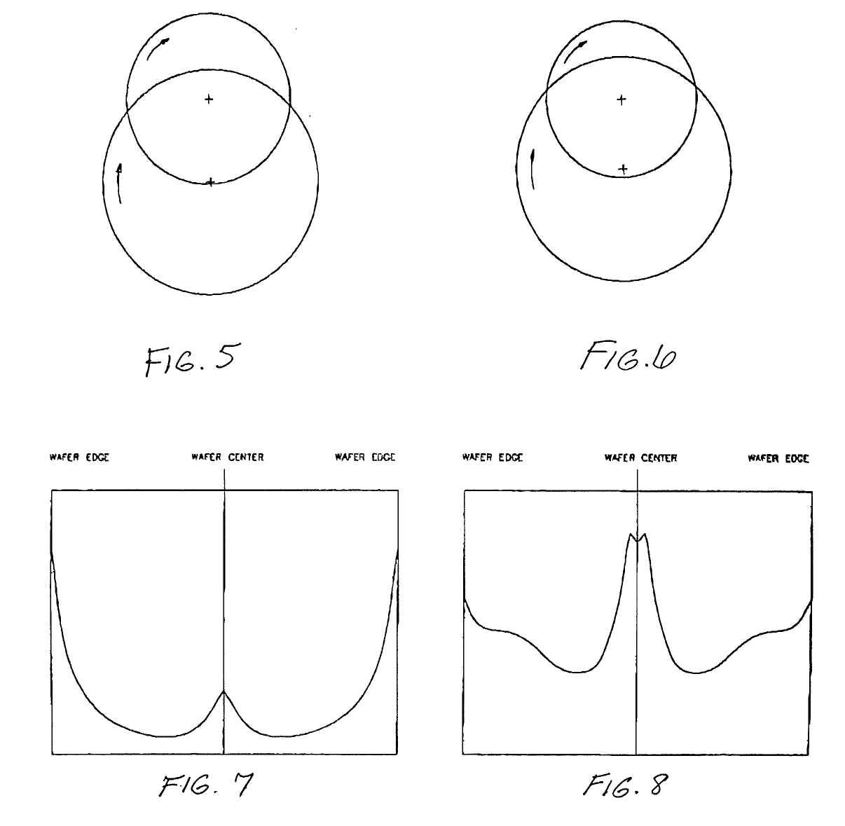

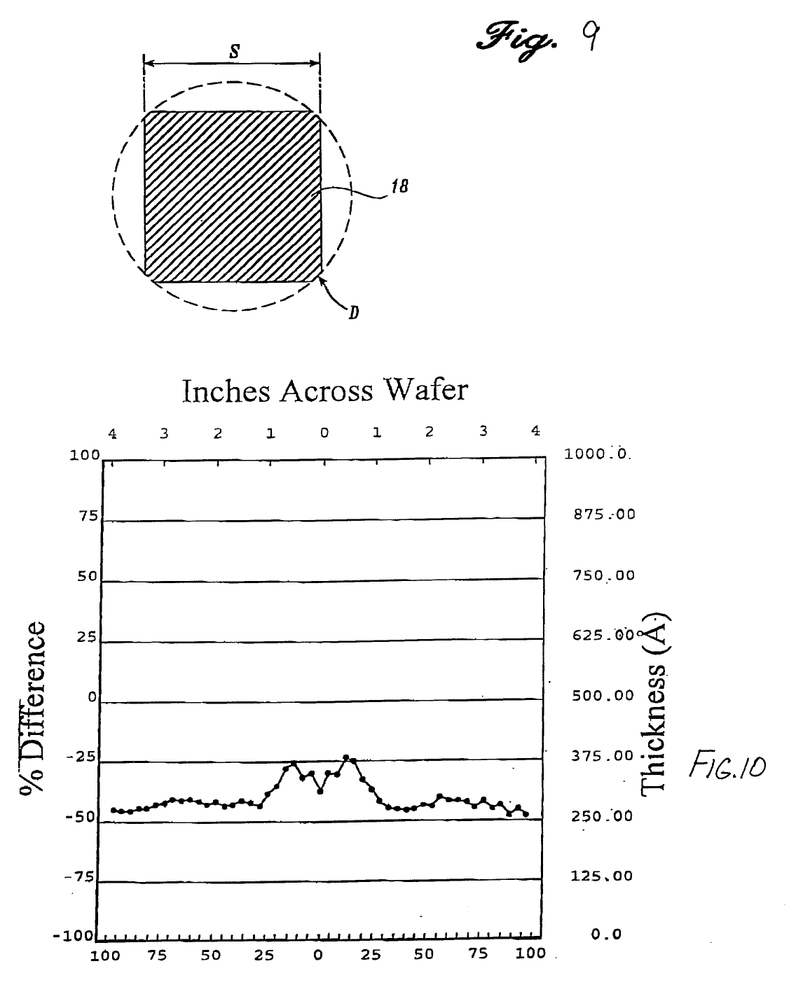

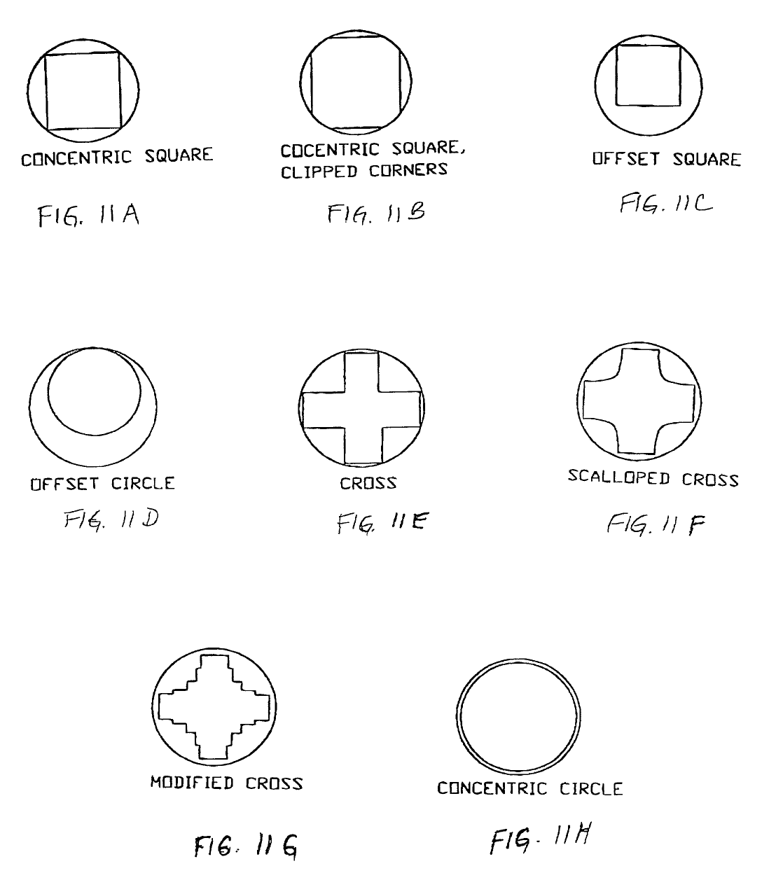

22. FIG. 7 is a diagram illustrating the resulting removal rate profile obtained by using the configuration of FIG. 5 and illustrates that the increased offset and pad size cause an edge fast removal rate profile.

23. FIG. 8 is a diagram illustrating the resulting removal rate profile obtained by using the configuration of FIG. 6 and illustrates the achieved balance between being edge fast and center fast.

24. FIG. 9 is a plan view illustrating a first embodiment of a buffing pad with a generally square shape.

25. FIG. 10 is a diagram illustrating the removal rate profile obtained by using the configuration of FIG. 6 in conjunction with the pad shape of FIG. 9.

26. FIGS. 11A-11H are plan views illustrating various embodiments of a buffing pad formed in accordance with the present invention.

27. FIG. 12a is a cross section of a standard wafer before etching.

28. FIG. 12b is a cross section of a standard wafer after etching and before barrier layer deposition.

29. FIG. 12c is a cross section of a standard wafer after barrier layer deposition and before plug metal deposition.

30. FIG. 12d is a cross section of a standard wafer after plug metal deposition.

31. FIG. 12e is a cross section of a standard wafer after planarization of the plug metal and before barrier layer planarization.

32. FIG. 12f is a cross section of a standard wafer after barrier layer removal.

33. FIG. 12g is a cross section of a standard wafer after metal interconnects have been added.

34. FIG. 12h is a cross section of a typical multilayer interconnect.

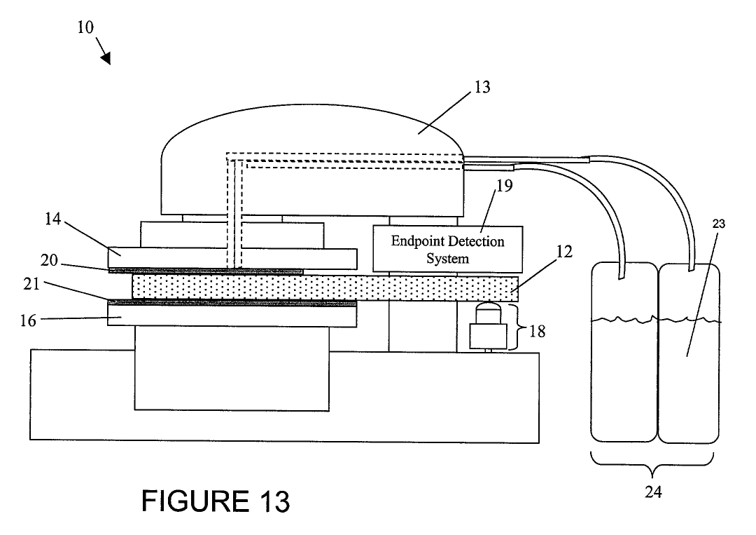

35. FIG. 13 is a cross section of an embodiment of the present invention.

36. FIG. 14 is a cross section of a standard primary polish station.

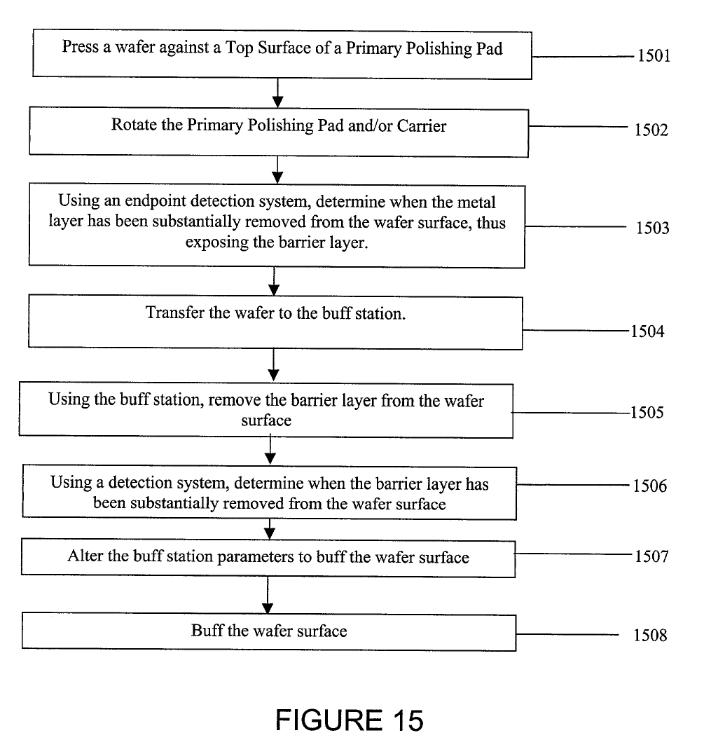

37. FIG. 15 is a diagram of one possible process for the invention.

### DETAILED DESCRIPTION OF THE PREFERRED EMBODIMENT

38. The present invention is an improvement to chemical-mechanical planarization equipment and methodology. The improvement can be applied to both buffing systems and primary polishing systems. The improvement includes using a buffing pad with a geometrically optimized shape and an optimized configuration of the offset O, overlay L, and buff head diameter, referred to herein as parameters.

39. FIG. 1 illustrates a known buff system 10 used to buff a wafer 12. In this example, buff system 10 is part of a 776 polisher, available from SpeedFam-IPEC Corp., Chandler, Ariz. Buff system 10 includes an arm 13; a buff head 14 with a polish pad 20 mounted thereon, a platen 16 with polish pad 21 mounted thereon, and roller supports 18. The roller supports 18 help hold the wafer 12 prior to buffing and also prevent lateral movement of the wafer 12 during buffing. During the buffing process, platen 16 moves upward to contact wafer 12, while buff head 14 moves downward to contact wafer 12 and apply a selected downforce. Buff head 14 and platen 16 then rotate, causing wafer 12 to rotate, thereby buffing the surface of wafer 12.

40. In this system, the buff head 14 has a diameter that is less than the diameter of wafer 12. The relative placement of buff head 14 and wafer 12 is illustrated in FIG. 2. During the buff process, the center of buff head 14 is offset from the center of wafer 12 by a distance O (referred to as the offset), with buff head 14 “overlapping” the center of wafer 12 by a distance L referred to herein as the overlay or overlap.

41. In a standard configuration (adapted for wafers 200 mm in diameter) of the aforementioned 776 buff system, the buff head is approximately 4.50 inches in diameter, with O being 4.43 cm (1.828 inches) and L being 1.067 cm (0.420 inches). This configuration is illustrated in FIG. 3. In this standard configuration, buff head 14 and lower platen 16 are rotated at approximately 300 rpm. The wafer 12 rotates at about 50 rpm due to friction and the offset of the system. With the conventional system, the removal rate profile illustrated in FIG. 4 is produced. This system achieved a non-uniformity of material removal from the wafer surface of about 60-70%. However, the ability to achieve a substantially planar wafer surface is preferred for removal of a material layer from the wafer surface at a buff station. The optimization of the buff station parameters as described below allows for the ability to effectively remove a material layer from the wafer surface.

42. Referring still to FIG. 4, the removal rate profile obtained using a standard buff configuration is center fast, meaning that more material is removed from the center of the wafer 12 than from the edge. The variation achieved in wafer 12 surface topography from before and after buffing is fairly significant, on the order of 375 angstroms.

43. FIG. 10 is a profile across the surface of a wafer 12 test structure to evaluate the planarity of the wafer 12 surface with an optimized buffing process in accordance with the present invention. As shown on the vertical axis, the degree of relative variation in wafer 12 surface material removal rate from before and after buffing is significantly decreased to approximately 100 angstroms, or about 10-15% nonuniformity. Applicants have discovered that the buffing process may be optimized to substantially improve the overall planarization process of the wafer 12. This improvement, in turn, allows for not only the removal of particulates and microscratches, but also for removal of a material layer, preferably the barrier layer 118 from the wafer 12 surface at the buff station 10.

44. The inventors herein have observed that the removal rate across a wafer 12 (i.e., removal rate profile) is dependent on the diameter of the buff head, the shape of the buff pad, the offset O and the overlay L. The inventors have observed that changing the buff head 14 diameter, buff pad 20 shape, offset O, and/or the overlay L alters the removal rate profile. These parameters affect the integrated relative velocity distribution (between a region of the wafer 12 and the portion of the buff pad 20 contacting that region of the wafer), as well as dwell time under the buff pad 20. Thus, by appropriately changing these parameters, the removal rate profile can be controlled. As used herein, the integrated relative velocity distribution refers to an area integration of the relative velocity due to the buff pad 20 rotation with respect to a rotating coordinate system fixed to the wafer 12 surface. The result of integrating the relative velocity is an integrated distribution that is a function of the distance from the center of the wafer 12. The integrated distribution is significant because the relative velocity distribution is one indicator of the relative material removal rate at a given point on the wafer 12. The integrated distribution does not take into account other factors such as the interaction of chemicals and liquid abrasives (slurries) and the distribution of these agents.

45. FIGS. 5 and 6 are schematic plan views illustrating different buffing unit configurations. The configuration of FIG. 5 uses a larger buffing pad than the configuration of FIG. 3, increases the offset, and decreases the overlap. The configuration of FIG. 6 uses a larger buffing pad and offset than the configuration of FIG. 3 but smaller than that of FIG. 5, while decreasing the overlap compared to the configuration of FIG. 3 but not as much as in the configuration of FIG. 5. Table 1 summarizes the offsets, overlaps, buff head diameter, removal rate profile characteristics, pad shape and standard deviation of the removal rate over the wafer diameter.

TABLE 1

| | | | Buff Head | | |
|---|---|---|---|---|---|
| | Offset | Overlap | Diameter | | Standard |
| Configuration | (in) | (in) | (in) | Buff Pad Shape | Deviation |
| Original FIG. 3 | 1.828 | .420 | 4.50 | Round | 52% |
| | 2.917 | .084 | 6.00 | Round | 71% |
| | 2.442 | .310 | 5.50 | Round | 24% |
| | 2.442 | .310 | 5.50 | Square (4.06″ side) | 10.2% |
| | 2.442 | .310 | 5.50 | 4.75″ diameter eccentric | 10.1% |

46. The resulting removal rates profiles of the configurations of FIGS. 5 and 6 are shown in FIGS. 7 and 8, respectively. As can be seen, FIGS. 7 and 8 show that the removal rate profiles for the configurations of FIGS. 5 and 6 are “edge fast” and “center fast and edge fast”, respectively.

47. One of the reasons that the configuration of FIG. 5 is edge fast is that the edge of the wafer has a relatively large dwell time under the buffing pad because the edge of the wafer is aligned near the center of the buffing pad. As a result, the wafer edge is in contact with the buffing pad for a longer duration (dwell time). In contrast, in the standard configuration (FIG. 3), the edge of the wafer is aligned near the edge of the buffing pad resulting in the wafer edge having a relatively low dwell time. Further, the wafer edge moves in more nearly the same direction as the buffing pad, thereby reducing the relative velocity difference, thereby reducing removal rate. The removal rate near the center of the wafer is relatively high for the conventional configuration due to the 100% dwell time and the high integrated velocity distribution. This creates the undesirable property of a highly non-uniform removal rate profile.

48. On the other hand, the configuration of FIG. 6 is both edge fast and center fast (see the associated removal rate profile of FIG. 8). The offset in this configuration causes the wafer edge to be aligned fairly near the center of the buffing pad, which increases the dwell time of the wafer edge. However, because the offset and the buff pad are smaller in this configuration compared to the configuration of FIG. 5, the removal rate at the wafer edge is slightly lower. Thus, this configuration demonstrates a balance between being edge fast and center fast.

49. Once an optimal offset and overlap configuration is achieved, the inventors appreciated that further improvements in the uniformity of the removal rate profile can be realized by changing the shape of the pad on the polish head. In one embodiment, pad material is removed from the outer portion of the polish pad to decrease the removal rate at both the edge and the center of the wafer, thereby improving the removal rate uniformity of the system.

50. Although the removal rate profiles of FIGS. 4, 7 and 8 may be desirable in certain applications, in general, a uniform removal rate profile is desired. The inventors appreciated that appropriate shaping of the buffing pad can improve the uniformity of the removal rate profile.

51. FIG. 9 illustrates a first embodiment of a buffing pad 18 formed in accordance with the present invention. The shape is essentially that of a square with portions of the squares corners clipped or rounded. In the embodiment shown in FIG. 9, the pad has a side length, S, in the range of about 9.9 cm to about 10.6 cm, with one particular embodiment having a length of about 10.3 cm (˜4.06 inches) with the comers rounded to match the buff head diameter. In this case, the square is not completely inscribed within the circular buff head, but instead has the rounded comers as shown in FIG. 9. In light of the present disclosure, those skilled in the art will appreciate that the size of the square will vary depending on the diameter of the wafer being processed.

52. FIG. 10 is a diagram illustrating the removal rate profile obtained using the buffing pad of FIG. 9. As can be seen in FIG. 10, the removal rate profile is significantly more uniform. In tests, the standard deviation of the removal rate across the wafer diameter was reduced to approximately 10.2%.

53. In addition to the embodiments described with reference to FIGS. 3-11, other pad shapes are possible that will also reduce the amount of pad material along the pad outer edge, e.g., star shapes, wheel spoke shapes, triangles, etc. Example shapes are shown in FIGS. 11A-11H. FIG. 11A shows a “concentric square” buffing pad (i.e., concentric with the buff head). FIG. 11B shows a “concentric square with clipped corners” buffing pad similar to that shown in FIG. 9. FIG. 11C shows a “offset square” buffing pad (i.e., offset with respect to the axis of rotation of the buff head). FIG. 11D shows an “offset circular” buffing pad where the buffing pad is smaller than the buff head and is tangent at one point so that pure rotation of the buff head produces an orbital type of motion of the pad. FIG. 11E shows a “cross” buffing pad. FIG. 11F shows a “scalloped cross” buffing pad. FIG. 11G shows a “modified cross” buffing pad. FIG. 11H shows a concentric circular buffing pad with a diameter smaller than that of the buff head. The actual removal rate profile for these configurations tend to vary. These different removal rate profiles can be optimal for a particular application. For example, the polishing process performed before the buffing process may result in a center fast or edge fast removal rate profile. An appropriate buffing unit configuration, including buffing pad shape, can be determined to compensate for the resulting topography after the primary polishing process.

54. While the preferred embodiment of the invention has been illustrated and described, it will be appreciated that various changes can be made therein without departing from the spirit and scope of the invention. For example, the buff pad may include grooves or slurry holes. Further, the present invention may be applied to other, more primary, processes in which a rotating head is pressed to a circular wafer for the purpose of removing portions of the wafer surface. In this regard, the term “buff” pad and “buffing” as used herein are generically defined to mean a material removing article including a primary polish step.

55. In another preferred embodiement of the invention, the planarization process is improved by allowing for removal of a material layer, preferably a barrier layer, on a buff station rather than on a primary polishing station. Unlike conventional CMP processes, this invention removes the interaction between multiple slurries used on the primary polishing station and also reduces the frequency of the need for conditioning the primary polish pad between removal steps. Also, removal of material from the wafer on the buff station occurs at a lower, more controlled rate than material removal on the primary polish pad. This lessens the amount of dishing that occurs at the plug and via areas. This invention thus reduces the amount of time necessary for processing as well as enhances the quality of planarization of the wafer surface.

56. The subject matter of the present invention is particularly suited for use in connection with Chemical Mechanical Planarization (“CMP”) of substrates or semiconductor wafers. As a result, an exemplary embodiment of the present invention is described in that context. It should be recognized, however, that such description is not intended as a limitation on the use or applicability of the present invention, but is instead provided to enable a complete description of an exemplary embodiment. For example, the substrate being subjected to CMP may comprise a workpiece other than a silicon wafer, such as a flat panel display, a magnetic computer memory disc, a read-write head, or the like.

57. One exemplary method for planarizing a front surface of a wafer 12 in accordance with the present invention will now be described with respect to FIGS. 12 and 15. FIG. 12h illustrates a typical semiconductor device. The wafer 12 has a well region 102 underlying an interlevel dielectric (ILD) layer 104 as shown in FIG. 12a. The first ILD layer 104 may be formed of silicon dioxide, but may also be formed of other dielectric materials such as silicon nitride, as well as other materials having a low dielectric constant, including fluorinated silicon dioxide or organic polymers. After formation of the first ILD layer 104, the layer 104 is etched to form an opening 103 (FIG. 12b) that is coated with a barrier layer 118 (FIG. 12c). The barrier layer 118 may be comprised of Ta, Ti, TiN, or a combination of the above, and may comprise a thickness of approximately 100-600 angstroms. This barrier layer 118 is used to improve adhesion of the metal 116 and to provide a barrier to prevent unwanted diffusion of the metal 116 into the dielectric 104. After the barrier layer 118 is deposited in the etchings and on the dielectric 104, a layer of plug metal 116, typically copper or tungsten is deposited over the barrier layer 118, as shown in FIG. 12d. At this stage, the wafer is loaded in a primary polish station, such as shown in FIG. 14, and pressed against the top surface of a primary polish pad (step 1501). The primary polish pad and/or carrier is then rotated (step 1502), thereby performing CMP on the plug metal 116 at the primary polish station 401 and primary polish pad 404, in the presence of slurry 405. The chemical slurry 405 is generally comprised of a polishing agent, such as alumina or silica, which is used as an abrasive material. Additionally, the slurry 405 may contain selected chemicals to etch or oxidize selected surfaces of the wafer 12 to prepare them for removal by the abrasive.

58. An endpoint detection system 407 (FIG. 14) is used to determine the point at which the metal layer has been substantially removed from the wafer 12 surface, thereby exposing a barrier layer 118 (step 1503). Such a system 407 might be comprised of motor current detection, infra red based temperature change detection, or optical sampling techniques such as white light, infra red, or laser. When the plug metal 116 has been planarized to the point where the underlying barrier layer 118 becomes exposed (FIG. 12e), the wafer 12 is transferred to the buff station 10 shown in FIG. 13 (step 1504).

59. At the buff station 10, the polishing of the barrier layer 118 is commenced using a second slurry 23 from a slurry delivery system 24. This slurry delivery system 24 may comprise an apparatus capable of delivering one or more slurries 23, separately or in combination. The slurries 23 may comprise an abrasive suspension separately or in conjunction with an acid, base, acqueous solution, or water. Therefore, the slurry composition may be altered or diluted between the step of barrier layer 118 removal and the step of buffing the wafer 12 surface. This second slurry 23 is preferably less chemically corrosive to the plug metal 116 and contains fewer abrasive particles.

60. The barrier layer 118 is then substantially removed (FIG. 12f) from the wafer surface (step 1505). Metalzed contacts 106 are thus embedded in the ILD layer 104. After the wafer 12 is transferred from the primary polish station 401 to the buff station 10, another wafer may be loaded in the primary polish station 401 for CMP removal of the plug metal 116, thus improving throughput.

61. The preferred rotation speed of the buff head 14 with attached buff pad 20 is approximately 350 rpm. The lower platen 16 and attached pad 21 are preferably rotated at approximately 300 rpm. An example of a pad used on the buff station is Politex Sureme™ by Rodell Corporation, with offices in Phoenix, Ariz. These pads are typically comprised of a polyurethane or other suitable material. The pressure exerted on the wafer 12 by the buffer system during polishing may be approximately 3 psi. Typical removal rates of the barrier layer 118 on the buff station 10 using the above disclosed process are approximately 1000-3000 angstroms/minute. Because a typical barrier layer 118 is approximately 200-1000 angstroms thick, this step will last for approximately 4-60 seconds, depending on the removal rate and the barrier layer 118 thickness.

62. Using a detection system on the buff station, the point at which the barrier layer 118 has been substantially removed from the wafer surface is detected (step 1506). Various techniques may be employed to determine endpoint, including a variety of optical, motor current, laser, or infra-red techniques. Optical sensors based on optical interference or ellipsometry are two examples of possible means for determining endpoint. Examples of optical endpoint detection systems may be seen in U.S. Pat. Nos. 5,972,162 and 6,106,662, and are hereby incorporated by reference. An example of a motor current method may be seen in U.S. Pat. No. 5,667,629 and is hereby incorporated by reference. After the barrier layer 118 has been substantially removed, the buff station parameters, including pressure, speed, and buff slurry 23, may be modified (step 1507) and the buff station 10 is then used to buff the wafer 12 (step 1508).

63. By utilizing this invention and removing the barrier layer at the buff station 10, the first polish pad 404 may be set up with a slurry 405 which polishes the metal layer 116 and the buff station 10 may be set up with a different slurry 23 to more effectively polish the barrier layer 118. Thus, the need for changing slurry compositions on the primary polishing station 401 is removed. After barrier layer 118 removal, the parameters of the buff station 10 may then be changed to buff the wafer surface 12.

64. The method of the present invention allows both the polishing slurry and the polishing pad configuration to be different for the metal layer 118 (primary polishing station 401) removal versus the barrier layer 118 (buff station 10) removal. Different polishing pads and slurries may be beneficial for metal CMP than for barrier layer removal. For example, a more abrasive pad may be used at the primary polish station 401 to allow for faster removal of bulk metal material. In addition, the planarization process is improved by minimizing metal dishing and field oxide erosion on the wafer surface because the buff station 10 may remove material from the wafer 12 surface in a more controlled manner.

65. In the preferred embodiment of the present invention, the same pads are used for both barrier layer 118 removal and buffing at the buff station 10. The same slurry may also be used, but diluted with water between barrier layer 118 removal and buffing steps.

66. Another advantage to removal of the barrier layer 118 on the buff station 10 is the ability to begin polishing a second wafer while the first wafer 12 is at the buff station 10. The steps in such a process cycle may include loading a wafer 12 in a carrier 403 at a primary polishing station 401, where a metal layer 116 is removed. The barrier layer 118 may then be removed on the buff station 10, followed by a buffing process. The wafer 12 may then be unloaded from the buff station 10. At the point in the process in which the wafer 12 has been transferred to the buff station 10, pad conditioning on the primary polishing station 401 may immediately commence if necessary. A second wafer's metal layer may then be polished on the primary polishing station 401 while the first wafer 12 is at the buff station 10 which improves machine throughput. Additionally, by removing the barrier layer 118 on the buff station 10, the time the wafer 12 spends on the primary polishing station 401 is reduced. This shorter polish time results in shorter polish pad conditioning time, which further increases throughput.

67. While embodiments herein have been described for use with copper, it is well understood that the present invention may be utilized to perform CMP on other metals, such as tungsten or aluminum. In such cases, the chemical oxidizer and the abrasive slurry component may change depending on the particular metallurgy, as is well known in the art. That is, conventional CMP slurries may be utilized in connection with tungsten, copper, or aluminum. Further, the present invention may be beneficially utilized in, for example, a Shallow Trench Isolation (STI) polishing process. In an STI process in accordance with the present invention, a dielectric layer is removed from the wafer surface on a conventional CMP polish station, leaving the underlying barrier layer exposed and substantially intact. The wafer is then moved from the CMP polish station to the buff station, where the barrier layer is subseqently removed.

68. The foregoing description of the invention is not intended to be exhaustive or to limit the invention to the precise form disclosed. Obviously, many modifications and variations will be apparent to practitioners skilled in this art. It is possible that the invention may be practiced to remove materials other than metal from the surface of a wafer. The embodiment was chosen and described in order to best explain the principles of the invention and its practical application, thereby enabling others skilled in the art to understand the invention for various embodiments and with various modifications as are suited for the particular use contemplated. It is intended that the scope of the invention be defined by the claims appended hereto and their equivalents.

What is claimed is:

1. An apparatus for removing a barrier layer from a semiconductor wafer comprising a buffing assembly, at least one buff pad, a slurry delivery system, and an endpoint detection system.

2. The apparatus of claim 1, wherein the slurry delivery system comprises one or more slurries which may be delivered separately or together.

3. The apparatus of claim 2, wherein the slurry used is chemically reactive to the barrier layer.

4. The apparatus of claim 1, wherein the endpoint detection system is comprised of an optical detection system.

5. The apparatus of claim 1, wherein the endpoint detection system is comprised of an infra red detection system.

6. The apparatus of claim 1, wherein the endpoint detection system is comprised of a laser detection system.

7. The apparatus of claim 1, wherein the endpoint detection system is comprised of a motor current detection system.

8. A method for processing a surface of a semiconductor wafer comprising the steps of:
a) removing a material layer overlying a barrier layer from the wafer surface at a primary polishing station with a primary polishing pad; and
b) removing the barrier layer from the wafer surface at a buff station using a set of buff station parameters.

9. The method of claim 8, further comprising the step of buffing the wafer surface after barrier layer removal.

10. The method of claim 9, wherein a set of buff station parameters may be different for the barrier layer removal step than for the buffing step.

11. The method of claim 8, wherein a different slurry composition is used for the barrier layer removal step than for the buffing step.

12. The method of claim 8, further comprising the step of detecting when the material layer is substantially removed from the wafer surface.

13. The method of claim 8, further comprising the step of detecting a point at which barrier layer removal is substantially complete.

14. The apparatus of claim 13, wherein the step of detecting a point at which barrier layer removal is substantially complete is accomplished using an endpoint detection system.

15. The apparatus of claim 14, wherein the endpoint detection system is comprised of an optical detection system.

16. The apparatus of claim 14, wherein the endpoint detection system is comprised of an infra red detection system.

17. The apparatus of claim 14, wherein the endpoint detection system is comprised of a laser detection system.

18. The apparatus of claim 14, wherein the endpoint detection system is comprised of a motor current detection system.

19. The method of claim 8 further comprising the step of conditioning the buff station pads.

20. The method of claim 19 wherein the conditioning step is accomplished by pressing a lower buff pad against an upper buff pad and rotating each pad at a different velocity.

21. The method of claim 19, wherein the pad conditioning step is performed between each wafer being processed.

22. The method of claim 19, wherein the pad conditioning step is performed between intermittent wafers being processed.

23. The method of claim 8, wherein the material layer is comprised of aluminum, copper, or tungsten.

24. The method of claim 8, wherein the barrier layer is comprised of Ti, TiN, Ta, or TaN.

25. The method of claim 8, further comprising the step of:
c) supplying a first polishing slurry to the primary polishing station; and
d) supplying one or more different polishing slurries to the buff station.
